(19) United States
(12) Patent Application Publication
(10) Pub. No.: US 2026/0186610 A1
(43) Pub. Date: Jul. 2, 2026

(54) DISPLAY DEVICE AND ELECTRONIC DEVICE USING THE SAME

(71) Applicant: Samsung Display Co., LTD., Yongin-si (KR)

(72) Inventors: Yoon A KIM, Yongin-si (KR); Seung Lyong BOK, Yongin-si (KR)

(21) Appl. No.: 19/310,425

(22) Filed: Aug. 26, 2025

(30) Foreign Application Priority Data
Dec. 31, 2024 (KR) 10-2024-0201727

(51) Int. Cl. G06F 3/044; G09G 3/3291; H10K 59/35; H10K 59/40; H10K 102/00

(52) U.S. Cl. CPC G06F 3/0446; G09G 3/3291; H10K 59/351; H10K 59/40; G09G 2320/0271; G09G 2354/00; G09G 2380/02; H10K 2102/311

(57) ABSTRACT

A display device includes a display panel including a first display unit, a second display unit that is folded with the first display unit in an in-folding manner, and a third display unit that is folded with the second display unit in an out-folding manner; a touch sensing unit arranged on a front surface of the first to third display units and configured to sense a user touch; and a display driving circuit configured to control an image display operation of pixels arranged in the first to third display units, wherein each of the second display unit and the third display unit includes a front surface and a rear surface through which light is transmitted based on a number and a size of light transmissive holes formed in a corresponding display area.

### CROSS-REFERENCE TO RELATED APPLICATION

The present application claims priority to and the benefit of Korean Patent Application No. 10-2024-0201727 filed on Dec. 31, 2024 in the Korean Intellectual Property Office, the disclosure of which in its entirety is herein incorporated by reference.

### BACKGROUND

### Field

Aspects of the present disclosure relate to a display device and an electronic device using the same.

### Description of the Related Art

With the advancement of the information age, the demand for various display devices for displaying images has increased. For example, display devices have been applied to various electronic devices such as smart phones, digital cameras, laptop computers, navigators, and smart televisions.

A display device may be a flat panel display device such as a liquid crystal display device or an organic light emitting display device. The organic light emitting display device of the flat panel display device may include a light emitting element in which each of pixels of a display panel may self-emit light, thereby displaying an image even without a backlight unit that provides light to the display panel. Also, the organic light emitting display device may display an image in a transparent or semi-transparent state through a manufacturing method such as using a transparent substrate or forming a light transmissive hole.

Recently, there has been a growing desire to provide mobility for users when using a display device. In particular, various mobile display devices that have performances comparable to not only mobile phones but also tablet PCs, laptops, and desktops are being sold.

The above information disclosed in this Background section is only for enhancement of understanding of the background of the invention and therefore it may contain information that does not form.

### SUMMARY

Aspects of some embodiments of the present disclosure are directed to a display device that is divided into transparent (or semi-transparent) display units and opaque display units, which are folded to overlap each other, to selectively display images with different characteristics through the transparent display units and the opaque display units, and an electronic device using the same.

Aspects of some embodiments of the present disclosure are directed to a display device that may improve image display quality of a low gray scale of transparent display units by utilizing an overlap structure of the transparent display units and improve luminance and definition in the outermost and edge areas, and an electronic device using the same.

Aspects of some embodiments of the present disclosure are directed to a display device that may provide additional specific functions of displaying images for supporting specific functions such as a keyboard by utilizing structural characteristics of transparent display units that overlap each other, and generating vibration and sound effects, and an electronic device using the same.

Aspects of some embodiments of the present disclosure are not limited to those mentioned above and additional aspects of the present disclosure, which are not mentioned herein, will be clearly understood by those skilled in the art from the following description of the present disclosure.

According to some embodiment of the present disclosure, there is provided a display device including: a display panel including a first display unit, a second display unit that is folded with the first display unit in an in-folding manner, and a third display unit that is folded with the second display unit in an out-folding manner; a touch sensing unit arranged on a front surface of the first to third display units and configured to sense a user touch; and a display driving circuit configured to control an image display operation of pixels arranged in the first to third display units, wherein each of the second display unit and the third display unit includes a front surface and a rear surface through which light is transmitted based on a number and a size of light transmissive holes formed in a corresponding display area.

In some embodiments, the first display unit is configured to display an image through a first display area through which external light is not transmitted and a first folding area extending in one direction of the first display area, the second display unit extends in one direction of the first folding area, and is configured to display an image through a second display area through which light is transmitted to the front and rear surfaces of the second display unit, and a second folding area extending in one direction of the second display area, and the third display unit extends in one direction of the second folding area, and is configured to display an image through a third display area through which light is transmitted to the front and rear surfaces of the third display unit.

In some embodiments, the first folding area is formed in an in-folding structure in which the first display area of the first display unit and the second display area of the second display unit are inwardly arranged to face each other, and the second folding area is formed in an out-folding structure in which the second display area and the third display area are outwardly arranged so that the rear surfaces of the second display area and the third display area face each other.

In some embodiments, the first display area includes a plurality of first unit pixels arranged in a matrix structure, including first to third subpixels or first to fourth subpixels, and is configured to display an image through the plurality of first unit pixels arranged in the matrix structure, the second and third display areas include a plurality of second unit pixels arranged in a matrix structure, including first to third subpixels and at least one light transmissive hole, and the plurality of second unit pixels are configured to display an image through the first to third subpixels and to transmit light in front and rear directions through the light transmissive hole.

In some embodiments, the first display unit includes an opaque substrate, through which external light is not transmitted, as a base substrate, and each of the second and third display units includes a transparent substrate, through which light is transmitted, as a base substrate.

In some embodiments, the display driving circuit is configured to: arrange first image data to display a first image according to a light non-transmissive area through the first display area and the first folding area, arrange second image data to display a second image according to a light transmissive area through the second display area among the second and third display areas that overlap each other and are folded, align image data in at least one frame unit by arranging third image data to display a third image according to a light transmissive area through the third display area among the second and third display areas that overlap each other and are folded, modulate a portion of the image data aligned in at least one frame unit, including the first to third image data, which corresponds to at least one horizontal line, into analog data voltages, and sequentially supply the analog data voltages to first to third subpixels of the first display area, the first folding area, the second display area, and the third display area.

In some embodiments, the display driving circuit arranges first image data to display a first image according to a light non-transmissive area through the first display area and the first folding area, arranges second image data to display a second image according to a light transmissive area in the second display area among the second and third display areas that overlap each other and are folded, aligns image data in at least one frame unit by arranging third image data to display a background image of a preset low gray scale or a background image of a black gray scale as a third image in the third display area or a preset partial area of the third display area among the second and third display areas that overlap each other and are folded, modulates a portion of the image data aligned in at least one frame unit, including the first to third image data, which corresponds to at least one horizontal line, into analog data voltages, and sequentially supplies the analog data voltages to first to third subpixels of the first display area, the first folding area, the second display area, and the third display area.

In some embodiments, at least one reflective electrode is further formed at an outmost portion of the second and third display areas, at each subpixel being arranged adjacent to the outmost portion in a preset number unit, and at a side adjacent to each subpixel, and a portion of the reflective electrode overlaps a pixel electrode formed in a light emission area of each subpixel or surrounds at least one outer side of the light emission area while partially overlapping the light emission area, thereby reflecting light emitted from the light emission area in front and side directions.

In some embodiments, the at least one reflective electrode includes a metal material that is the same as that of the pixel electrode, and the at least one reflective electrode is arranged to partially overlap the pixel electrode and a pixel defining layer in a front direction of the pixel electrode, or is formed and arranged to surround at least one outer side and front surface of the light emission area while partially overlapping the light emission area on the front surface of the light emission area.

In some embodiments, the touch sensing unit further includes a pressure sensing element including first and second electrodes arranged to face each other with a touch insulating layer interposed between the first and second electrodes, and the display driving circuit is configured to supply a vibration driving signal to a vibration generating module in response to a pressure sensing signal from the pressure sensing element.

According to some embodiment of the present disclosure, there is provided an electronic device including: a display device configured to display an image; an image signal processor configured to control an image display timing of the display device; and a power module configured to provide a power signal to the display device, wherein the display device includes: a display panel including a first display unit, a second display unit that is folded with the first display unit in an in-folding manner, and a third display unit that is folded with the second display unit in an out-folding manner; a touch sensing unit arranged on a front surface of the first to third display units and configured to sense a user touch; and a display driving circuit configured to control an image display operation of pixels arranged in the first to third display units.

In some embodiments, each of the second display unit and the third display unit include a front surface and a rear surface through which light is transmitted based on a number and a size of light transmissive holes formed in a corresponding display area, the first display unit is configured to display an image through a first display area through which external light is not transmitted and a first folding area extending in one direction of the first display area, the second display unit extends in one direction of the first folding area, and is configured to display an image through a second display area through which light is transmitted to the front surface and a rear surface of the second display unit, and a second folding area extending in one direction of the second display area, and the third display unit extends in one direction of the second folding area, and is configured to display an image through a third display area through which light is transmitted to the front surface and a rear surface of the third display unit.

In some embodiments, the first folding area is formed in an in-folding structure in which the first display area of the first display unit and the second display area of the second display unit are inwardly arranged to face each other, and the second folding area is formed in an out-folding structure in which the second display area and the third display area are outwardly arranged so that the rear surfaces of the second display area and the third display area face each other.

In some embodiments, the first display area includes a plurality of first unit pixels arranged in a matrix structure, including first to third subpixels or first to fourth subpixels, and is configured to display an image through the plurality of first unit pixels arranged in the matrix structure, the second and third display areas include a plurality of second unit pixels arranged in a matrix structure, including first to third subpixels and at least one light transmissive hole, and the plurality of second unit pixels are configured to display an image through the first to third subpixels and to transmit light in front and rear directions through the light transmissive hole.

In some embodiments, the first display unit includes an opaque substrate, through which external light is not transmitted, as a base substrate, and each of the second and third display units includes a transparent substrate, through which light is transmitted, as a base substrate.

In some embodiments, the display driving circuit is configured to: arrange first image data to display a first image according to a light non-transmissive area through the first display area and the first folding area, arrange second image data to display a second image according to a light transmissive area through the second display area among the second and third display areas that overlap each other and are folded, align image data in at least one frame unit by arranging third image data to display a third image according to a light transmissive area through the third display area among the second and third display areas that overlap each other and are folded, modulate a portion of the image data aligned in at least one frame unit, including the first to third image data, which corresponds to at least one horizontal line, into analog data voltages, and sequentially supply the analog data voltages to first to third subpixels of the first display area, the first folding area, the second display area, and the third display area.

In some embodiments, the display driving circuit arranges first image data to display a first image according to a light non-transmissive area through the first display area and the first folding area, arranges second image data to display a second image according to a light transmissive area in the second display area among the second and third display areas that overlap each other and are folded, aligns image data in at least one frame unit by arranging third image data to display a background image of a preset low gray scale or a background image of a black gray scale as a third image in the third display area or a preset partial area of the third display area among the second and third display areas that overlap each other and are folded, modulates a portion of the image data aligned in at least one frame unit, including the first to third image data, which corresponds to at least one horizontal line, into analog data voltages, and sequentially supplies the analog data voltages to first to third subpixels of the first display area, the first folding area, the second display area, and the third display area.

In some embodiments, at least one reflective electrode is further formed at an outmost portion of the second and third display areas, at each subpixel being arranged adjacent to the outmost in a preset number unit, and at a side adjacent to each subpixel, and a portion of the reflective electrode overlaps a pixel electrode formed in a light emission area of each subpixel or surrounds at least one outer side of the light emission area while partially overlapping the light emission area, thereby reflecting light emitted from the light emission area in front and side directions.

In some embodiments, the at least one reflective electrode includes a metal material that is the same as that of the pixel electrode, and the at least one reflective electrode is arranged to partially overlap the pixel electrode and a pixel defining layer in a front direction of the pixel electrode, or is formed and arranged to surround at least one outer side and front surface of the light emission area while partially overlapping the light emission area on the front surface of the light emission area.

In some embodiments, the touch sensing unit further includes a pressure sensing element including first and second electrodes arranged to face each other with a touch insulating layer interposed between the first and second electrodes, and the display driving circuit is configured to supply a vibration driving signal to a vibration generating module in response to a pressure sensing signal from the pressure sensing element.

In the display device and the electronic device using the same according to some embodiments of the present disclosure, images with different characteristics may be selectively displayed through transparent (or semi-transparent) display units and opaque display units, which are folded to overlap each other, so that image display efficiency may be increased and user satisfaction may be enhanced.

In addition, image display quality of a low gray scale of the transparent display unit and luminance and definition of an outer area may be increased using an overlap structure of the transparent display units. In particular, specific images and functions such as a keyboard may be additionally provided through the transparent display units that are arranged in duplicate, so that user satisfaction may be further improved.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a foldable-type display device according to some embodiments of the present disclosure;

FIG. 2 is a perspective view illustrating a folding structure of first and second transparent display units shown in FIG. 1, according to some embodiments of the present disclosure;

FIG. 3 is a perspective view illustrating a folding shape of the first and second transparent display units and an opaque display unit, which are shown in FIGS. 1 and 2, according to some embodiments of the present disclosure;

FIG. 4 is a front view illustrating a display panel included in the display device according to some embodiments of the present disclosure;

FIG. 5 is a detailed side cross-sectional view illustrating the display panel shown in FIG. 4, according to some embodiments of the present disclosure;

FIG. 6 is a schematic layout view illustrating a third display area of a third display unit shown in FIGS. 1 to 3, according to some embodiments of the present disclosure;

FIG. 7 is a schematic layout view illustrating an example of a touch sensing unit according to some embodiments of the present disclosure;

FIG. 8 is a perspective view illustrating light transmittance characteristics of folded second and third display units and a first display unit in a non-folded state, according to some embodiments of the present disclosure;

FIG. 9 is a view illustrating image display characteristics of folded second and third display units and a first display unit in a non-folded state, according to some embodiments of the present disclosure;

FIG. 10 is a perspective view illustrating a light transmittance modulation mode of folded second and third display units, according to some embodiments of the present disclosure;

FIG. 11 is a view illustrating another image display characteristics using folded second and third display units, according to some embodiments of the present disclosure;

FIG. 12 is a perspective view illustrating a foldable-type display device according to some other embodiments of the present disclosure;

FIG. 13 is a perspective view illustrating a light transmittance modulation mode of a third display unit shown in FIG. 12, according to some embodiments of the present disclosure;

FIG. 14 is a cross-sectional view illustrating a structure of the display device shown in FIG. 6 taken along the line A-A′, according to some embodiments of the present disclosure;

FIG. 15 is a cross-sectional view illustrating a structure of the display device shown in FIG. 6 taken along the line A-A′, according to some other embodiments of the present disclosure;

FIG. 16 is a block diagram illustrating an electronic device including a display device according to some embodiments of the present disclosure; and

FIG. 17 illustrates schematic diagrams of electronic devices according to some embodiments of the present disclosure.

### DETAILED DESCRIPTION

The present disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The display device and/or any other relevant devices or components according to embodiments of the present invention described herein may be implemented utilizing any suitable hardware, firmware (e.g., an application-specific integrated circuit), software, or a suitable combination of software, firmware, and hardware. For example, the various components of the display device may be formed on one integrated circuit (IC) chip or on separate IC chips. Further, the various components of the display device may be implemented on a flexible printed circuit film, a tape carrier package (TCP), a printed circuit board (PCB), or formed on a same substrate. Further, the various components of the display device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Each of the features of the various embodiments of the present disclosure may be combined or combined with each other, in part or in whole, and technically various interlocking and driving are possible. Each embodiment may be implemented independently of each other or may be implemented together in an association.

Hereinafter, detailed embodiments will be described with reference to the accompanying drawings.

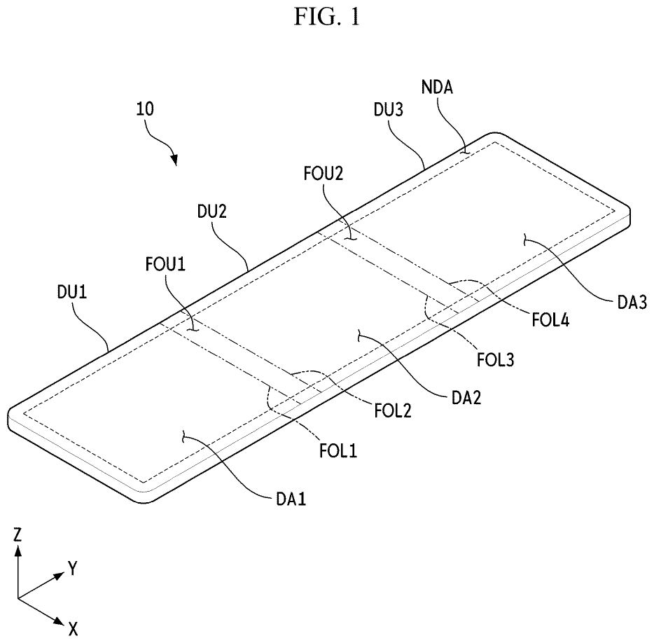

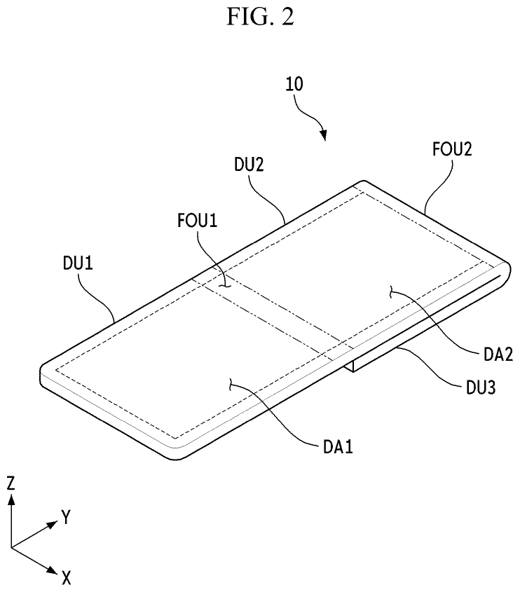

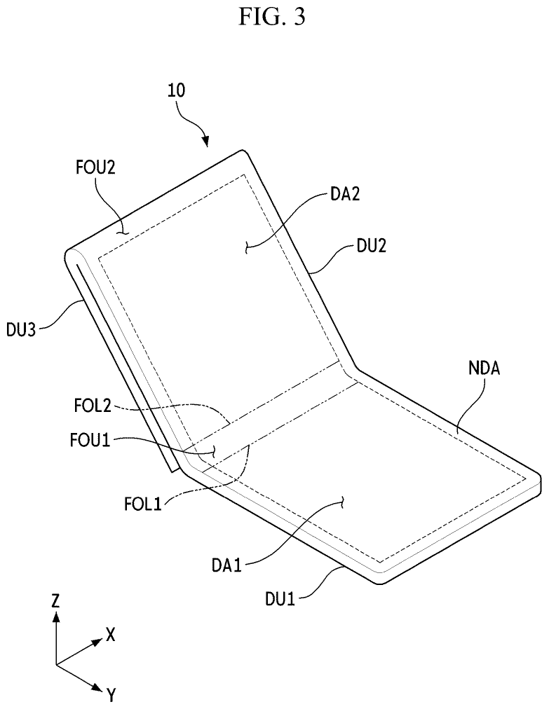

FIG. 1 is a perspective view illustrating a foldable-type display device according to some embodiments of the present disclosure. FIG. 2 is a perspective view illustrating a folding structure of first and second transparent display units shown in FIG. 1, according to some embodiments of the present disclosure. FIG. 3 is a perspective view illustrating a folding shape of the first and second transparent display units and an opaque display unit, which are shown in FIGS. 1 and 2, according to some embodiments of the present disclosure.

Referring to FIGS. 1 to 3, a display device 10 according to some embodiments includes a first display unit DU1, a second display unit DU2 that is folded with the first display unit DU1 in an in-folding manner (i.e., the second display unit DU2 is inwardly folded with respect to the first display unit DU1), and a third display unit DU3 that is folded with the second display unit DU2 in an out-folding manner (i.e., second display unit DU2 is outwardly folded with respect to the first display unit DU1).

In the present disclosure, a first direction (e.g., the X-axis direction) may be a short side or transverse direction of the folded display device 10, for example, a horizontal direction of the display device 10. A second direction (e.g., the Y-axis direction) may be a long side or longitudinal direction of the folded display device 10, for example, a vertical direction of the display device 10. A third direction (e.g., the Z-axis direction) may be a thickness direction of the display device 10.

The first display unit DU1 of the display device 10 displays an image through a first display area DA1 in which external light is not transmitted from the outside through the first display area DA1 (e.g., in through the front surface and out through the rear surface, and vice versa) and a first folding area FOU1 extended in one direction (e.g., the second direction (e.g., the X-axis direction)) of the first display area DA1.

In the first display area DA1, red, green, and blue subpixels or red, green, blue, and white subpixels are arranged to display an image. In the first display unit DU1, an opaque substrate through which light is not transmitted may be used as a base substrate so that external light is not transmitted from the outside through the first display area DA1 (e.g., in through the front surface and out through the rear surface, and vice versa).

The second display unit DU2 extends in one direction (e.g., the second direction (e.g., the Y-axis direction)) of the first display unit DU1 through the first folding area FOU1. The first folding area FOU1 is interposed between the second display unit DU2 and the first display unit DU1. The second display unit DU2 displays an image through a second display area DA2, through which light is transmitted to the front and rear surfaces of the second display unit DU2, and a second folding area FOU2 extended in one direction (e.g., the X-axis direction) of the second display area DA2.

A plurality of light transmissive holes penetrated in the third direction (e.g., the Z-axis direction), which is the thickness direction, are arranged in the second display area DA2 together with red, green, and blue subpixels, or red, green, blue, and white subpixels. External light is transmitted through the plurality of light transmissive holes passing through the front and rear surfaces of the second display area DA2. In addition, an image is displayed through red, green, and blue subpixels or red, green, blue, and white subpixels, which are arranged in the second display area DA2. In the second display unit DU2, a transparent substrate such as a glass substrate through which light is transmitted is used as a base substrate, so that light may be transmitted to the front and rear surfaces of the second display area DA2 by the light transmissive holes and the transparent substrate.

The third display unit DU3 extends in one direction, for example, a second direction (e.g., the Y-axis direction) of the second display unit DU2 through the second folding area FOU2. The second folding area FOU2 is interposed between the third display unit DU3 and the second display unit DU2. The third display unit DU3 displays an image through the third display area DA3 through which light is transmitted to the front surface and the rear surface of the third display unit DU3.

The plurality of light transmissive holes penetrated in the third direction (e.g., the Z-axis direction), which is the thickness direction, are arranged in the third display area DA3 together with red, green, and blue subpixels, or red, green, blue, and white subpixels. External light is transmitted through the plurality of light transmissive holes passing through the front and rear surfaces of the third display area DA3. In addition, an image is displayed through red, green, and blue subpixels or red, green, blue, and white subpixels, which are arranged in the third display area DA3. In the third display unit DU3, a transparent substrate such as a glass substrate through which light is transmitted is used as a base substrate, so that light may be transmitted to the front and rear surfaces by the light transmissive holes and the transparent substrate. An image non-display area NDA may be formed outside the first to third display areas DA1, DA2, and DA3 and the first and second folding areas FOU1 and FOU2.

FIGS. 1 to 3 illustrate a foldable display device in which the second display unit DU2 and the third display unit DU3 of the display device 10 may be folded in an in-folding manner and an out-folding manner along the second direction (e.g., the Y-axis direction). The display device 10 may be transformed or maintained in a number of states including a folded state in which the display device 10 is folded at least once in an in-folding manner and an out-folding manner, a flex state that is bent only at a selected angle, and a flat state that is fully unfolded.

The first folding area FOU1 of the first display unit DU1 may be formed in an in-folding structure in which the first display area DA1 of the first display unit DU1 and the second display area DA2 of the second display unit DU2 are inwardly arranged to face each other.

The first folding area FOU1 is arranged to extend in the first direction (e.g., the X-axis direction) between the first and second display areas DA1 and DA2, and may be formed in a structure that is in-folded in the second direction (e.g., the Y-axis direction). In other words, the first and second folding lines FOL1 and FOL2 that distinguish the first folding area FOU1 from the first and second display areas DA1 and DA2 extend in the first direction (e.g., the X-axis direction), and the first and second display units DU1 and DU2 may be in-folded in the second direction (e.g., the Y-axis direction).

When the first folding area FOU1 is folded in an in-folding manner, the front surfaces of the first and second display areas DA1 and DA2 may be arranged to face each other. In this way, when the first folding area FOU1 extends in the first direction (e.g., the X-axis direction) and is in-folded in the second direction (e.g., the Y-axis direction), an area of the display device 10 in the second direction (e.g., the Y-axis direction) may be reduced to about ⅔ of the display device area in the flat (e.g., unfolded) state.

On the other hand, the second folding area FOU2 of the second display unit DU2 is formed in an out-folding structure in which the second display area DA2 of the second display unit DU2 and the third display area DA3 of the third display unit DU3 are outwardly arranged so that the rear surfaces of the second display area DA2 and the third display area DA3 face each other.

The second folding area FOU2 is arranged to extend in the first direction (e.g., the X-axis direction) between the second and third display areas DA2 and DA3, and may be formed in a structure that is out-folded in the second direction (e.g., the Y-axis direction). In other words, the third and fourth folding lines FOL3 and FOL4 that distinguish the second folding area FOU2 from the first and second display areas DA1 and DA2 extend in the first direction (e.g., the X-axis direction), and the second and third display units DU2 and DU3 may be out-folded in the second direction (e.g., the Y-axis direction).

As shown in FIG. 2, when the second folding area FOU2 is folded in an out-folding manner, the rear surfaces of the second and third display areas DA2 and DA3 may be arranged to face each other. In this way, when the second folding area FOU2 extends in the first direction (e.g., the X-axis direction) and is out-folded in the second direction (e.g., the Y-axis direction), an area of the display device 10 in the second direction (e.g., the Y-axis direction) may be reduced to about ⅔ of the display device area in the flat (e.g., unfolded) state.

When the display device 10 is unfolded as shown in FIG. 1, an image may be displayed in the front direction in the first display area DA1, the second folding area DA2, and the third display area DA3 of the display device 10. On the other hand, when the first display unit DU1 and the second display unit DU2 are in-folded by the first folding area FOU1 and the third display unit DU3 is out-folded in a rear direction of the second display unit DU2 by the second folding area FOU2, an area of the display device 10 in the second direction (e.g., the Y-axis direction) may be reduced to about ⅓ of the display device area in the flat (e.g., unfolded) state.

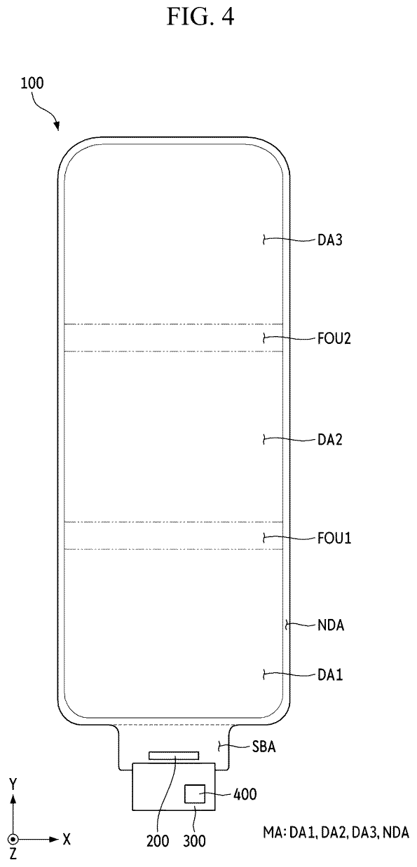

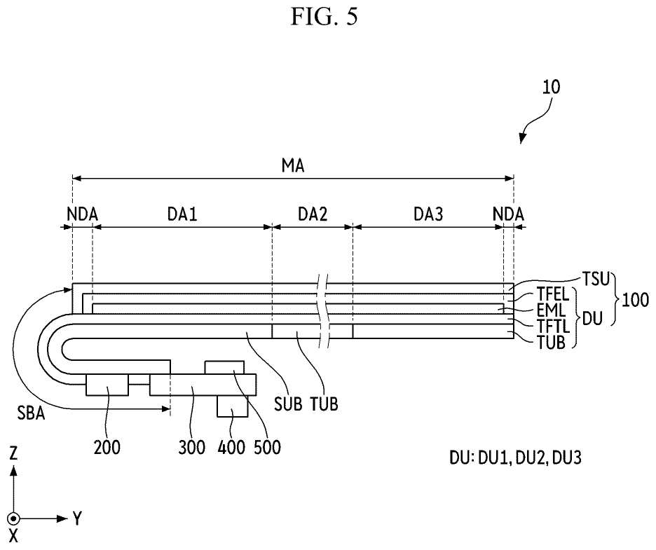

FIG. 4 is a detailed front view illustrating a display panel included in the display device according to some embodiments of the present disclosure. FIG. 5 is a detailed side cross-sectional view illustrating the display panel shown in FIG. 4, according to some embodiments of the present disclosure.

Referring to FIGS. 4 and 5, the display device 10 according to some embodiments may be variously classified depending on a display manner. For example, the display device 10 may be classified into an organic light emitting display (OLED), an inorganic light emitting display (inorganic EL), a quantum dot light emitting display (QED), a micro-LED, a nano-LED, etc. Hereinafter, an organic light emitting display (OLED) will be described as the display device 10 of some embodiments by way of example, and the organic light emitting display (OLED) will be abbreviated as the display device 10 unless a special classification is appropriate. The display device 10 according to some embodiments is not limited to the organic light emitting display (OLED), and other display devices listed above or known in the art may be applied within the range that shares the technical spirits.

As shown in FIGS. 4 and 5, the display device 10 includes a touch sensing module, and the touch sensing module includes a touch sensing unit TSU arranged on a front surface of a display panel 100, and at least one touch driving circuit 400 that generates touch coordinate data of the touch sensing unit TSU.

In detail, the display panel 100 of the display device 10 includes first to third display units DU1, DU2, and DU3 displaying an image, and the touch sensing unit TSU is arranged on the first to third display units DU1, DU2, and DU3 of the display panel 100 to sense a touch of a body portion, such as a finger, and a touch input device, such as an electronic pen.

A plurality of pixels may be included in the first to third display units DU1, DU2, and DU3 of the display panel 100, and an image may be displayed through the plurality of pixels. Each pixel may include red, green, and blue pixels, or may include red, green, blue, and white pixels.

In the second and third display areas DA2 and DA3 of the second and third display units DU2 and DU3, a plurality of light transmissive holes penetrated together with the red, green, and blue pixels, in the third direction (e.g., the Z-axis direction), which is a thickness direction, are further formed and arranged in parallel with the pixels. Accordingly, in case of the second and third display areas DA2 and DA3, some external light is transmitted by the light transmissive holes passing through the front surface and the rear surface. That is, while an image is displayed through the red, green, and blue pixels in the second and third display areas DA2 and DA3, selected light may be transmitted through the light transmissive holes formed in parallel with the pixels.

The touch sensing unit TSU may be packaged in a front direction of the display panel 100 (e.g., a direction perpendicular to the front surface of the display panel 100), or may be formed integrally with the display panel 100 on the front surface of the display panel 100. The touch sensing unit TSU may include a plurality of touch electrodes and sense a user touch in a capacitance manner using the touch electrodes. The touch sensing unit TSU may be packaged on the display unit DU of the display panel 100, or may be formed integrally with the display unit DU.

The touch driving circuit 400 may be formed in a type of at least one microprocessor electrically connected to the touch sensing unit TSU, that is, each touch sensing area. The touch driving circuit 400 may supply touch driving signals to the touch electrodes arranged in the touch sensing unit TSU in a matrix structure and sense the amount of change in capacitance between the touch electrodes. The touch driving circuit 400 may check a user touch input based on the amount of change in capacitance between the touch electrodes and calculate touch coordinate data.

The display driving circuit 200 may control overall functions of the display device 10. For example, the display driving circuit 200 may receive touch coordinate data for the touch sensing unit TSU from the touch driving circuit 400 to determine a user touch coordinates and generate digital video data according to the touch coordinates. In addition, the display driving circuit 200 may execute an application indicated by an icon displayed on the user touch coordinates. As another example, the display driving circuit 200 may receive coordinate data from an electronic pen or the like to determine the touch coordinates of the electronic pen, and then may generate digital video data according to the touch coordinates or execute an application indicated by an icon displayed on the touch coordinates of the electronic pen.

The display driving circuit 200 may output control signals and data voltages for driving pixels arranged in the first to third display areas DA1, DA2, and DA3 and the first and second folding areas FOU1 and FOU2, for example, pixels divided into red, green, blue, white, etc.

In detail, the display driving circuit 200 divides and aligns external image data in at least one frame unit so that they are displayed in frame units through the first display area DA1, the first folding area FOU1, the second display area DA2, the second folding area FOU2 and the third display area DA3. In addition, the display driving circuit 200 modulates (or converts) the image data arranged in frame units into analog data voltages as much as at least one horizontal line (i.e., modulates a portion of the image data arranged in frame units, which corresponds to at least one horizontal line, into analog data voltages), and supplies the data voltages to data lines connected to the pixels of the first display area DA1, the first folding area FOU1, the second display area DA2, the second folding area FOU2 and the third display area DA3.

Referring to FIGS. 4 and 5, the display panel 100 may be largely classified into a main area MA and a sub-area SBA. The main area MA may include first to third display areas DA1, DA2, and DA3 and first and second folding areas FOU1 and FOU2, in which pixels displaying an image are provided, and a non-display area NDA which is an outer area and a peripheral area.

The non-display area NDA may be a peripheral area of the first to third display areas DA1, DA2, and DA3 and the first and second folding areas FOU1 and FOU2, that is, an outer area thereof. The non-display area NDA may include at least one gate driver supplying gate signals to gate lines, and fan-out lines connecting the display driving circuit 200 to the first to third display areas DA1, DA2, and DA3, and the first and second folding areas FOU1 and FOU2.

The sub-area SBA may extend from one side of the main area MA. The sub-area SBA may include a flexible material capable of being subjected to bending, folding, rolling, or the like. For example, when the sub-area SBA is bent, the sub-area SBA may overlap the main area MA in the thickness direction (e.g., the Z-axis direction). The sub-area SBA may include a display driving circuit 200 and a pad portion connected to the circuit board 300. In some examples, the sub-area SBA may be omitted, and the display driving circuit 200 and the pad portion may be arranged in the non-display area NDA.

The circuit board 300 may be attached onto the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

An opaque substrate SUB and a transparent substrate TUB of the display panel 100 shown in FIG. 5 may be base substrates or base members. The opaque substrate SUB and the transparent substrate TUB may be flat types. In some examples, the opaque substrate SUB and the transparent substrate TUB may be flexible substrates capable of being subjected to bending, folding, rolling, or the like. For example, the opaque substrate SUB and the transparent substrate TUB may include a glass material or a metal material, but are not limited thereto. For another example, the opaque substrate SUB and the transparent substrate TUB may include a polymer resin such as polyimide (PI) and/or the like.

A thin film transistor layer TFTL may be arranged on the opaque substrate SUB and the transparent substrate TUB. The thin film transistor layer TFTL may include a plurality of thin film transistors constituting a pixel circuit of each of the pixels. The thin film transistor layer TFTL may further include gate lines, data lines, power lines, gate control lines, fan-out lines connecting the display driving circuit 200 with the data lines, and lead lines connecting the display driving circuit 200 with the pad portion. When the gate driver is formed on each of one side and the other side of the non-display area NDA of the display panel 100, the gate driver may also include thin film transistors.

The thin film transistor layer TFTL may be selectively arranged in the first to third display areas DA1, DA2, and DA3, the first and second folding areas FOU1 and FOU2, the non-display area NDA, and the sub-area SBA. Thin film transistors, the gate lines, the data lines, and the power lines of each of the pixels of the thin film transistor layer TFTL may be arranged in the first to third display areas DA1, DA2, and DA3, and the first and second folding areas FOU1 and FOU2. The gate control lines and the fan-out lines of the thin film transistor layer TFTL may be arranged in the non-display area NDA. The lead lines of the thin film transistor layer TFTL may be arranged in the sub-area SBA.

A light emitting element layer EML may be arranged on the thin film transistor layer TFTL. The light emitting element layer EML may include a plurality of light emitting elements in which a first electrode, a light emitting layer, and a second electrode are sequentially stacked to emit light, and a pixel defining layer defining each of the pixels. The light emitting elements of the light emitting element layer EML may be arranged in the first to third display areas DA1, DA2, and DA3, the first and second folding areas FOU1 and FOU2, and the non-display area NDA.

An encapsulation layer TFEL may cover an upper surface and a side of the light emitting element layer EML, and may protect the light emitting element layer EML. The encapsulation layer TFEL may include at least one inorganic layer and at least one organic layer to encapsulate the light emitting element layer EML.

The touch sensing unit TSU including the touch sensing area may be arranged on the main area MA and the encapsulation layer TFEL of the display panel 100. The touch sensing area of the touch sensing unit TSU may include a plurality of touch electrodes for sensing a user touch in a capacitance manner, and touch driving lines for connecting the plurality of touch electrodes with at least one touch driving circuit 400. The touch electrodes are arranged in each touch sensing area in a matrix structure to sense a user touch in a self-capacitance manner or a mutual capacitance manner.

The touch sensing unit TSU may not be integrally formed on the display panel 100, but be arranged on a separate substrate or film arranged on the display panel 100. In such examples, the substrate or film supporting the touch sensing unit TSU may be a base member for encapsulating the main area MA. Hereinafter, an example in which the touch sensing unit TSU is integrally formed on the front surface of the main area MA will be described.

The plurality of touch electrodes may be arranged in the touch sensing area that overlaps the main area MA. On the other hand, the touch lines that transmit touch driving signals or touch sensing signals may be arranged in a touch peripheral area that overlaps the non-display area NDA.

The touch driving circuit 400 for generating touch coordinate data for the touch sensing area may be arranged in the non-display area NDA or the sub-area SBA of the display panel 100. In some examples, the touch driving circuit 400 for generating touch coordinate data may be packaged on a separate circuit board 300. The touch driving circuit 400 may be formed as an integrated circuit (IC).

The touch driving circuit 400 supplies the touch driving signals to the touch electrodes of the touch sensing area that overlaps the main area MA, and measures the amount of change in charges of mutual capacitance of each of a plurality of touch nodes formed by the touch electrodes. In such examples, the touch driving circuit 400 measures a change in capacitance of the touch nodes in accordance with a voltage magnitude or the amount of change in a current of the touch sensing signal received through the touch electrodes. In this way, the touch driving circuit 400 may determine a user touch position depending on the amount of change in charges of mutual capacitance of each of the touch nodes. The touch driving signal may be a pulse signal having a frequency. The touch driving circuit 400 calculates whether there is a touch input of a touch input device or a user's body portion such as a finger for each touch sensing area and touch coordinates based on the amount of change in capacitance between the touch electrodes for each touch sensing area.

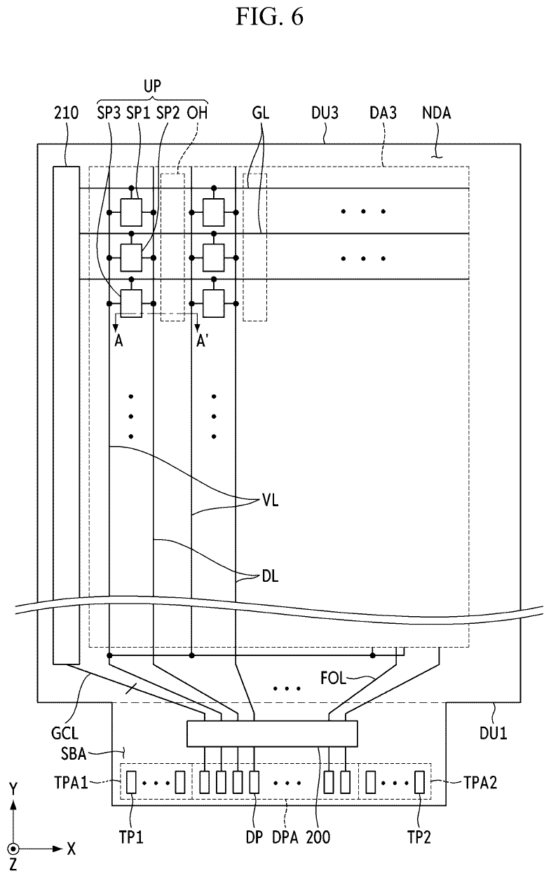

FIG. 6 is a schematic layout view illustrating a third display area of a third display unit shown in FIGS. 1 to 3, according to some embodiments of the present disclosure. In detail, FIG. 6 is a layout view partially illustrating a third display area DA3 of the third display unit DU3 and a non-display area NDA in a state before the touch sensing unit TSU is formed.

The third display area DA3 of the third display unit DU3 may be defined as a central area that includes the center of the third display unit DU3. For example, the third display area DA3 may include each unit pixel UP including a plurality of subpixels SP1, SP2, and SP3 and a light transmissive hole OH, a plurality of gate lines GL, a plurality of data lines DL, a plurality of power lines VL, and the like.

Each unit pixel UP may include first to third subpixels SP1, SP2, and SP3 and at least one light transmissive hole OH. The first to third subpixels SP1, SP2, and SP3 are defined as minimum units that output light of red, green, blue, and white. The light transmissive hole OH includes a transparent hole through which light is transmitted in a direction of front and rear surfaces, which is the thickness direction (the third direction (e.g., the Z-axis direction)) of the display panel 100, and may further include a light transmissive material layer (e.g., an organic or inorganic material layer) and a transparent substrate.

In the first display area DA1, the respective unit pixels UP including the first to third subpixels SP1, SP2, and SP3 or first to fourth subpixels are arranged in a matrix structure to display an image through the unit pixels UP. In case of the first display unit DU1, the opaque substrate SUB through which light is not transmitted may be used as a base substrate so that external light is not transmitted from the outside through the first display area DA1 (e.g., in through the front surface and out through the rear surface, and vice versa).

As shown in FIG. 6, in the second and third display areas DA2 and DA3, the respective unit pixels UP including the first to third subpixels SP1, SP2, and SP3 and at least one light transmissive hole OH are arranged in a matrix structure. Accordingly, the unit pixels arranged in the second and third display areas DA2 and DA3 in a matrix structure display images through the first to third subpixels SP1, SP2, and SP3, and transmit light in the direction of the front and rear surfaces (i.e., the direction perpendicular to the front and rear surfaces) through the light transmissive hole OH.

The plurality of gate lines GL may supply the gate signals received from at least one gate driver 210 to the plurality of first to third subpixels SP1, SP2, and SP3. The plurality of gate lines GL may extend in X-axis direction, and may be spaced apart from each other in Y-axis direction crossing the X-axis direction.

The plurality of data lines DL may supply the data voltages received from the display driving circuit 200 to the plurality of first to third subpixels SP1, SP2, and SP3. The plurality of data lines DL may extend in the Y-axis direction, and may be spaced apart from each other in the X-axis direction.

The plurality of power lines VL may supply a power voltage applied from the display driving circuit 200 or a separate power supply unit to the plurality of first to third subpixels SP1, SP2, and SP3. The power voltage may be at least one of a driving voltage, an initialization voltage, or a reference voltage. The plurality of power lines VL may extend in the Y-axis direction, and may be spaced apart from each other in the X-axis direction.

The non-display area NDA is a peripheral area surrounding the first to third display areas DA1, DA2, and DA3 and the first and second folding areas FOU1 and FOU2, and may be finally defined as a bezel area. The non-display area NDA may include a gate driver 210, fan-out lines FOL, and gate control lines GCL. The gate driver 210 may generate a plurality of gate signals based on the gate control signal, and may sequentially supply the plurality of gate signals to the plurality of gate lines GL in accordance with a set order.

The fan-out lines FOL may extend from the display driving circuit 200 to the first to third display areas DA1, DA2, and DA3 and the first and second folding areas FOU1 and FOU2. The fan-out lines FOL may supply the data voltage received from the display driving circuit 200 to the plurality of data lines DL.

The plurality of gate lines GL may supply the gate signal received from at least one gate driver 210 to the plurality of subpixels SP1, SP2, and SP3. The plurality of gate lines GL may extend in the X-axis direction, and may be spaced apart from each other in the Y-axis direction crossing the X-axis direction.

The display driving circuit 200 may output control signals and data voltages for driving the display panel 100 to the fan-out lines FOL. The display driving circuit 200 may supply the data voltage to the data line DL through the fan-out lines FOL. The data voltage may be supplied to the plurality of subpixels SP1, SP2, and SP3, and may determine display luminance for each of the plurality of subpixels SP1, SP2, and SP3. The display driving circuit 200 may supply the gate control signal to the gate driver 210 through the gate control line GCL.

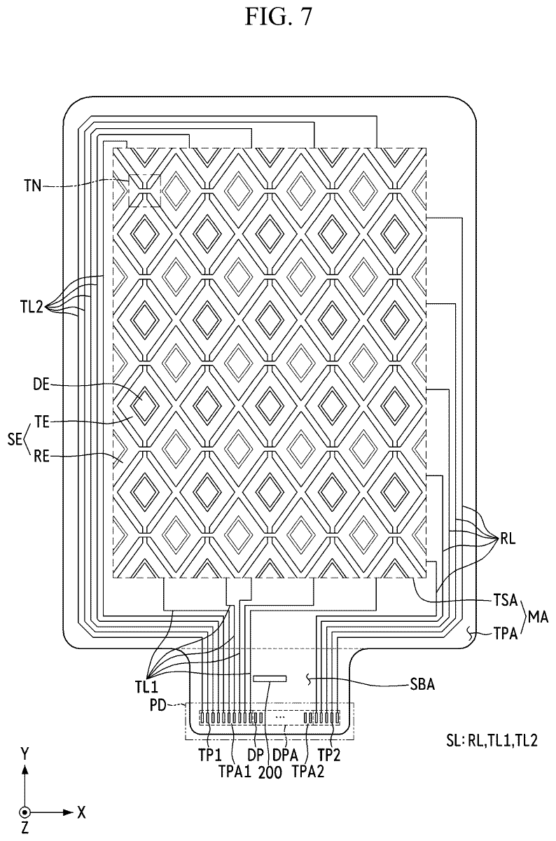

FIG. 7 is a schematic layout view illustrating an example of a touch sensing unit according to some embodiments of the present disclosure. In detail, FIG. 7 is a layout view illustrating a planar structure of the touch sensing area TSA corresponding to the main area MA.

Referring to FIG. 7, the touch sensing unit TSU may include a touch sensing area TSA for sensing a user touch, and a touch peripheral area TPA defined as a peripheral area of the touch sensing area TSA.

The touch sensing area TSA may overlap the main area MA including the non-display area NDA by covering the main area MA of the display unit DU. Because the non-display area NDA is a bezel area, outer areas of the touch sensing area TSA, which overlaps and correspond to the non-display area NDA, correspond to the bezel area.

The touch peripheral area TPA corresponds to an arrangement area of the gate driver 210. Accordingly, the touch sensing area TSA extends and is arranged on the non-display area NDA excluding the arrangement area of the gate driver 210, to overlap the non-display area NDA.

The touch sensing area TSA may include a plurality of touch electrodes SE and a plurality of dummy electrodes DM. The plurality of touch electrodes SE may form mutual capacitance or self-capacitance to sense an object or a person's touch. The plurality of touch electrodes SE may include a plurality of driving electrodes TE and a plurality of sensing electrodes RE.

The plurality of driving electrodes TE may be arranged in the X-axis direction and the Y-axis direction. The plurality of driving electrodes TE may be spaced apart from each other in the X-axis direction and the Y-axis direction. The driving electrodes TE adjacent to each other in the Y-axis direction may be electrically connected to each other through a plurality of connection electrodes.

The plurality of driving electrodes TE may be connected to first touch pads through the driving line TL. The driving line TL may include a lower driving line TL1 and an upper driving line TL2. For example, some of the driving electrodes TE arranged below the touch sensing area TSA may be connected to the first touch pads through the lower driving line TL1, and other ones of the driving electrodes TE arranged above the touch sensing area TSA may be connected to the first touch pads through the upper driving line TL2. The lower driving line TL1 may extend to the first touch pads by passing through a lower side of the touch peripheral area TPA. The upper driving line TL2 may extend to the first touch pads by passing through an upper side, a left side, and the lower side of the touch peripheral area TPA. In such examples, the touch pads that are not denoted may be pads formed on the circuit board 300 or the like and connected to at least one touch driving circuit 400.

The driving electrodes TE adjacent to each other in the Y-axis direction may be electrically connected to each other by a plurality of connection electrodes, and even though any one of the plurality of connection electrodes is disconnected, the driving electrodes TE may be stably connected to each other through the other connection electrodes. The driving electrodes TE adjacent to each other may be connected by two connection electrodes, but the number of connection electrodes is not limited thereto. The connection electrode may be bent at least once. For example, the connection electrode may have a bent shape (“<” or “>”), but its planar shape is not limited thereto.

The connection electrode may be arranged on a different layer from the plurality of driving electrodes TE and the plurality of sensing electrodes RE. The driving electrodes TE adjacent to each other in the Y-axis direction may be electrically connected to each other through the connection electrode arranged on the different layer from the plurality of driving electrodes TE or the plurality of sensing electrodes RE. The connection electrodes may be formed on a rear layer (or a lower layer) on which the driving electrodes TE and the sensing electrodes RE are formed. The connection electrodes are electrically connected to each of the driving electrodes TE adjacent thereto through a plurality of contact holes. Accordingly, even though the connection electrodes overlap the plurality of sensing electrodes RE in the Z-axis direction, the plurality of driving electrodes TE may be insulated from the plurality of sensing electrodes RE. Mutual capacitance may be formed between the driving electrode TE and the sensing electrode RE.

The sensing electrodes RE adjacent to each other in the X-axis direction may be electrically connected to each other through a connection portion arranged on the same layer as the plurality of driving electrodes TE or the plurality of sensing electrodes RE. That is, the plurality of sensing electrodes RE may extend in the X-axis direction, and may be spaced apart from each other in the Y-axis direction. The plurality of sensing electrodes RE may be arranged in the X-axis direction and the Y-axis direction, and the sensing electrodes RE adjacent to each other in the X-axis direction may be electrically connected to each other through the connection portion.

Touch nodes TN are formed in areas where the connection electrodes CE connecting the driving electrodes TE cross the connection portion of the sensing electrodes RE, so that the touch nodes TN may be arranged in the touch sensing area TSA in a matrix form.

The plurality of sensing electrodes RE may be connected to second touch pads through sensing lines RL. For example, some of the sensing electrodes RE, which are arranged on a right side of the touch sensing area TSA, may be connected to the second touch pads through the sensing lines RL. The sensing lines RL may extend to the second touch pads by passing through the right and lower sides of the touch peripheral area TPA. The second touch pads may be connected to at least one touch driving circuit 400 through the circuit board 300.

Each of the plurality of dummy electrodes DE may be surrounded by the driving electrode TE or the sensing electrode RE. Each of the plurality of dummy electrodes DE may be insulated from the driving electrode TE or the sensing electrode RE by being spaced apart from the driving electrode TE or the sensing electrode RE. Thus, the dummy electrode DE may be electrically floated.

The touch driving circuit 400 supplies the touch driving signal to the plurality of driving electrodes TE. In addition, the touch driving circuit 400 receives a signal fed back from each of the plurality of driving electrodes TE as a touch sensing signal of the driving electrodes TE, and receives a touch sensing signal for the sensing electrodes RE from each of the plurality of sensing electrodes RE. Accordingly, the touch driving circuit 400 measures a change in the magnitude of the touch sensing signal received from the plurality of driving electrodes TE and the plurality of sensing electrodes RE, and thus measures the amount of change in charges of mutual capacitance of each of the touch nodes TN formed by the plurality of driving electrodes TE and the plurality of sensing electrodes RE. The touch driving circuit 400 may determine the user touch position and touch moving direction depending on the amount of change in charges of mutual capacitance of each of the touch nodes. In this way, the touch driving circuit 400 calculates whether there is a touch input of a touch input device or a user's body portion such as a finger for each touch sensing area and touch coordinates based on the amount of change in capacitance between the touch electrodes.

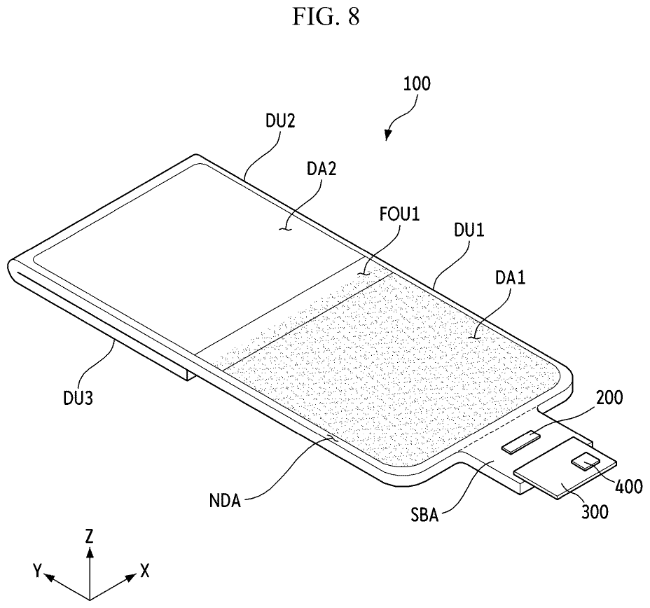

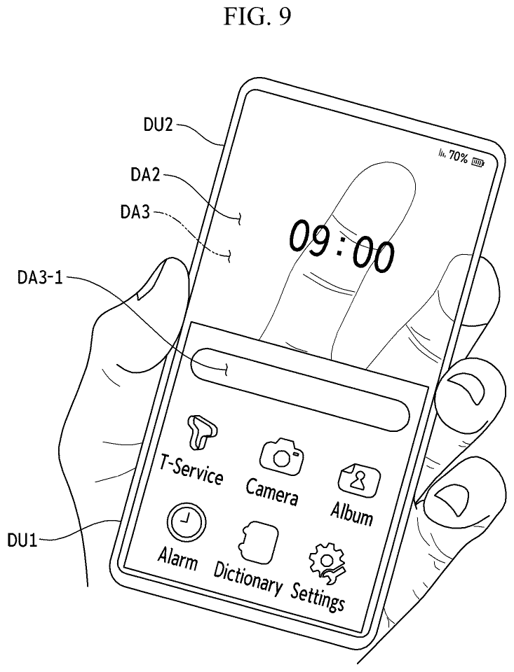

FIG. 8 is a perspective view illustrating light transmittance characteristics of folded second and third display units and a first display unit in a non-folded state, according to some embodiments of the present disclosure. FIG. 9 is a view illustrating image display characteristics of folded second and third display units and a first display unit in a non-folded state, according to some embodiments of the present disclosure;

Referring to FIGS. 8 and 9, the display driving circuit 200 arranges first image data to display a first image according to a light non-transmissive area through the first display area DA1 and the first folding area FOU1. The display driving circuit 200 arranges second image data to display a second image according to the light transmissive area through the second display area DA2 among the folded second and third display areas DA2 and DA3 that overlap each other. Also, the display driving circuit 200 arranges third image data to display a third image according to the light transmissive area through the third display area DA3 among the folded second and third display areas DA2 and DA3 that overlap each other, and aligns the image data in at least one frame unit.

The display driving circuit 200 modulates (or converts) image data aligned in a frame unit, including the first to third image data, into analog data voltages as much as at least one horizontal line (i.e., modulates a portion of the image data aligned in a frame unit, including the first to third image data, which corresponds to at least one horizontal line, into analog data voltages). In addition, the display driving circuit 200 sequentially supplies the modulated data voltages (or converted data voltages) to the first to third subpixels SP1, SP2, and SP3 of the first display area DA1, the first folding area FOU1, the second display area DA2, and the third display area DA3.

As shown in FIG. 9, the first image according to the light non-transmissive area is displayed in the first display area DA1 and the first folding area FOU1, and second and third images according to the light transmissive area are displayed in the second and third display areas DA2 and DA3. Because light is transmitted through the entire light transmissive holes OH in the second and third display areas DA2 and DA3, the second and third display areas DA2 and DA3 may display the second and third images in a transparent or semi-transparent state.

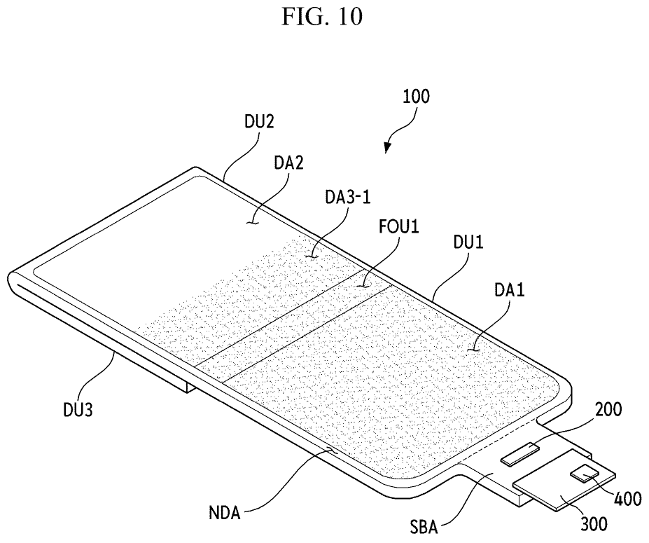

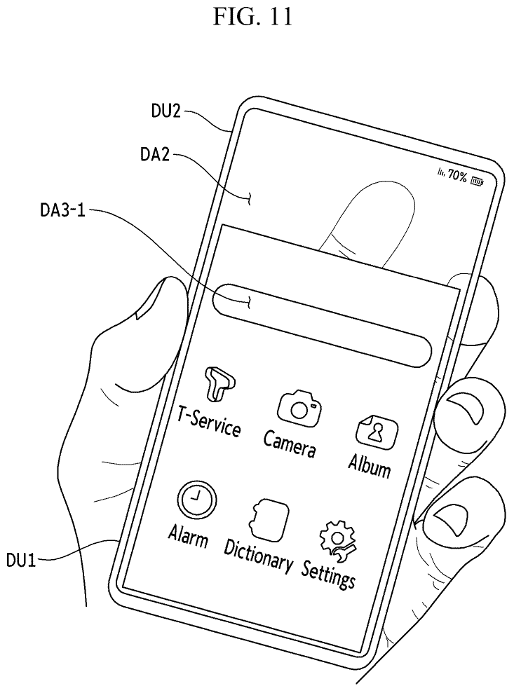

FIG. 10 is a perspective view illustrating a light transmittance modulation mode of folded second and third display units, according to some embodiments of the present disclosure. FIG. 11 is a view illustrating another image display characteristics using folded second and third display units, according to some embodiments of the present disclosure.

Referring to FIGS. 8 and 9, the display driving circuit 200 arranges first image data to display the first image according to the light non-transmissive area through the first display area DA1 and the first folding area FOU1. The display driving circuit 200 arranges second image data to display the second image according to the light transmissive area in the second display area DA2 among the folded second and third display areas DA2 and DA3 that overlap each other. Also, the display driving circuit 200 may arrange third image data to display a background image of a preset low gray scale or a background image of a black gray scale in the third display area DA3 or a preset partial area DA3-1 of the third display area DA3 among the folded second and third display areas DA2 and DA3 that overlap each other, as a third image, thereby aligning the image data in at least one frame unit.

The display driving circuit 200 modulates (or converts) the image data aligned in a frame unit, including the first to third image data, into analog data voltages as much as at least one horizontal line (i.e., modulates a portion of the image data aligned in a frame unit, including the first to third image data, which corresponds to at least one horizontal line, into analog data voltages). In addition, the display driving circuit 200 sequentially supplies the modulated data voltages (or the converted data voltages) to the first to third subpixels SP1, SP2, and SP3 of the first display area DA1, the first folding area FOU1, the second display area DA2, and the third display area DA3.

As shown in FIG. 11, the first image according to the light non-transmissive area is displayed in the first display area DA1 and the first folding area FOU1, and the second image according to the light transmissive area may be displayed in the second display area DA2. In such examples, a background image of a preset low gray scale or a background image of a black gray scale may be displayed in the third display area DA3 or a preset partial area DA3-1 of the third display area DA3 as a third image, thereby improving luminance and definition of the second image displayed in the second display area DA2.

When the background image of a preset low gray scale or the background image of a black gray scale is displayed in the third display area DA3 or a preset partial area DA3-1 of the third display area DA3, luminance and definition of the second image displayed in the second display area DA2 may be improved (e.g., increased), so that display quality of the image of a low gray scale displayed in the second display area DA2 may be improved (e.g., increased).

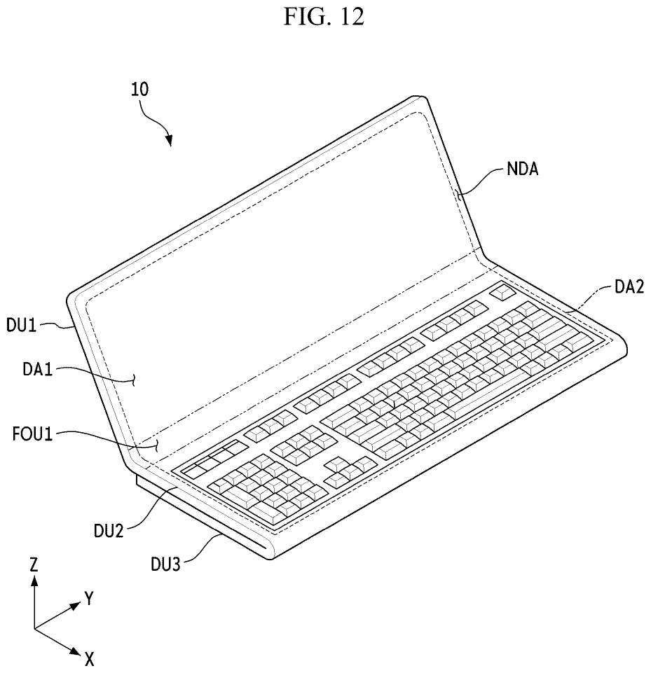

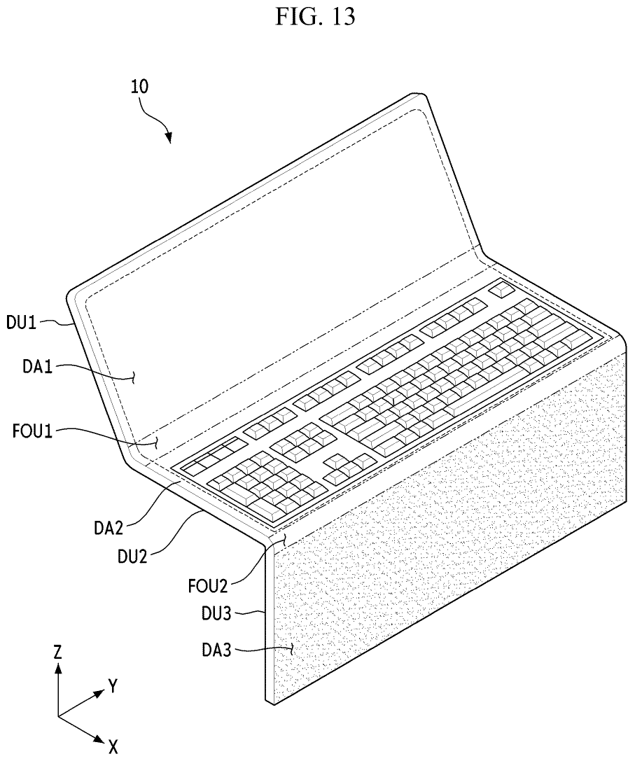

FIG. 12 is a perspective view illustrating a foldable-type display device according to some other embodiments of the present disclosure. FIG. 13 is a perspective view illustrating a light transmittance modulation mode of a third display unit shown in FIG. 12, according to some embodiments of the present disclosure.

Referring to FIGS. 12 and 13, the second display unit DU2 and the third display unit DU3 of the display device 10 may be arranged in a rear direction in a state that they overlap each other and are folded, and the first display unit DU1 may be maintained in a flex state bent only at a selected angle from the second display unit DU2.

The display driving circuit 200 arranges the second image data so that a functional image capable of performing and supporting a preset specific function such as a keyboard is displayed as a second image in the second display area DA2 among the folded second and third display areas DA2 and DA3 that overlap each other.

In such examples, the display driving circuit 200 may determine the user's functional image touch coordinates through the touch coordinate data detected through the touch driving circuit 400, and may arrange the first image data so that the functional image corresponding to the touch coordinates is displayed as the first image.

The display driving circuit 200 may arrange the image data in at least one frame unit by arranging the third image data so that a background image of a preset low gray scale or a background image of a black gray scale is displayed as a third image in the third display area DA3 among the folded second and third display areas DA2 and DA3 that overlap each other.

In the functional image display process, the display driving circuit 200 modulates (or converts) image data aligned in a frame unit, including the first to third image data, into analog data voltages as much as at least one horizontal line in real time (i.e., modulates a portion of the image data aligned in a frame unit, including the first to third image data, which corresponds to at least one horizontal line, into analog data voltages in real time). The display driving circuit 200 sequentially supplies the modulated data voltages (or converted data voltages) to the first to third subpixels SP1, SP2, and SP3 of the first display area DA1, the first folding area FOU1, the second display area DA2, and the third display area DA3.

The display driving circuit 200 receives a pressure sensing signal through at least one pressure sensing element formed in the touch sensing unit TSU of the display panel 100, especially a pressure sensing element of the touch sensing unit TSU corresponding to a front direction (e.g., a direction perpendicular to the front surface) of the second display area DA2. In addition, the display driving circuit 200 allows a vibration generating module 500 to generate vibration in accordance with the user touch operation in the second display area DA2 by supplying a vibration driving signal to the vibration generating module 500 in response to the pressure sensing signal. The pressure sensing element may be formed in the touch sensing unit TSU in a Quantum Tunneling Composite (QTC) element type or the like.

In the second and third display areas DA2 and DA3 of the second and third display units DU2 and DU3, because light may be transmitted by passing through the front surface and the rear surface of each by way of the light transmissive holes OH of each unit pixel UP, luminance and definition of an image displayed through each unit pixel UP may be deteriorated. For example, luminance and definition of the displayed image are inevitably deteriorated as the unit pixels UP are arranged at the outermost portions of the second and third display areas DA2 and DA3 and arranged adjacent to the outmost portions. Accordingly, at least one reflective electrode may be additionally formed at the outmost portion of the second and third display areas DA2 and DA3, at each of the subpixels SP1, SP2, and SP3 arranged adjacent to the outmost in a preset number unit, and at a side adjacent to each of the subpixels SP1, SP2, and SP3.

Each reflective electrode may be formed and arranged so that a portion of the reflective electrode overlaps the light emitting layer of the light emitting elements of each of the subpixels SP1, SP2, and SP3 arranged at the outermost areas and adjacent to the outermost areas or surrounds at least one outer side of the light emitting layer while partially overlapping the light emitting layer of the light emitting elements, thereby reflecting light emitted from the light emitting layer in a front direction (e.g., toward a user of the display device 10 in a direction perpendicular to the front surface of the display panel 100).

The image display light of each of the subpixels SP1, SP2, and SP3 arranged at the outermost and adjacent to the outermost of the second and third display areas DA2 and DA3 may be additionally reflected by the reflective electrodes arranged adjacent to each other. Accordingly, the image display light of each of the subpixels SP1, SP2, and SP3 arranged at the outermost and adjacent to the outermost may be reflected by the reflective electrodes, so that its luminance and definition may be increased.

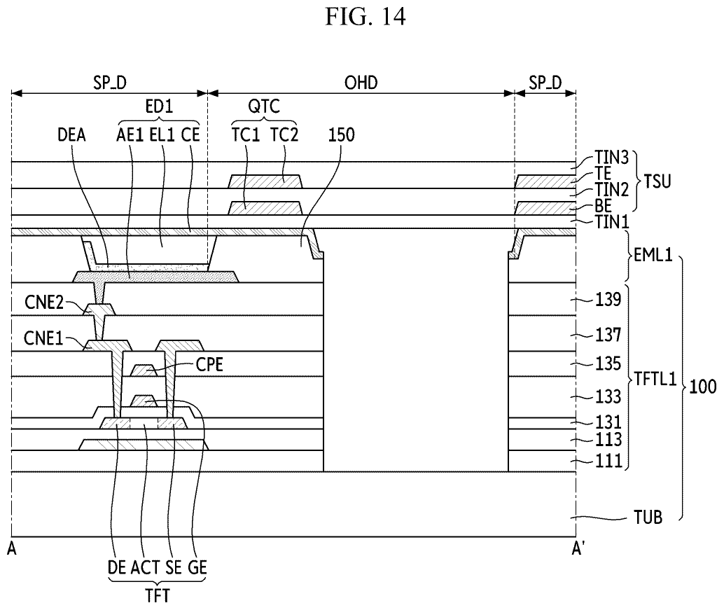

FIG. 14 is a cross-sectional view illustrating a structure of display device taken along the line A-A′ of FIG. 6, according to some embodiments of the present disclosure.

Referring to FIG. 14, the first thin film transistor layer TFTL1 in which thin film transistors TFT of the first to third subpixels SP1, SP2, and SP3 are formed is arranged on the base substrate such as the transparent substrate TUB.

The first thin film transistor layer TFTL1 may include a first buffer layer 111, a lower metal layer BML, a second buffer layer 113, a thin film transistor TFT, a gate insulating layer 131, a first interlayer insulating layer 133, a capacitor electrode CPE, a second interlayer insulating layer 135, a first connection electrode CNE1, a first passivation layer 137, a second connection electrode CNE2, and a second passivation layer 139.

The first buffer layer 111 may be arranged on the substrate SUB. The first buffer layer 111 may include an inorganic layer capable of preventing or substantially reducing permeation of the air or moisture. For example, the first buffer layer 111 may include a plurality of inorganic layers that are alternately stacked.

The lower metal layer BML may be arranged on the first buffer layer 111. For example, the lower metal layer BML may be formed as a single layer or multi-layers made of any one of molybdenum (Mo), aluminum (Al), chromium (Cr), gold (Au), titanium (Ti), nickel (Ni), neodymium (Nd) and copper (Cu), or their alloy.

The second buffer layer 113 may cover the first buffer layer 111 and the lower metal layer BML. The second buffer layer 113 may include an inorganic layer capable of preventing or substantially reducing permeation of the air or moisture. For example, the second buffer layer 113 may include a plurality of inorganic layers that are alternately stacked.

The thin film transistor TFT may be arranged on the second buffer layer 113, and may constitute a pixel circuit of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE. The thin film transistor TFT may include a low-temperature polysilicon thin film transistor LTPS as well as an oxide thin film transistor.

The semiconductor layer ACT may be arranged on the second buffer layer 113. The semiconductor layer ACT may overlap the lower metal layer BML and the gate electrode GE in the thickness direction, and may be insulated from the gate electrode GE by the gate insulating layer 131. A material of the semiconductor layer ACT may be conductorized so that a portion of the semiconductor layer ACT may form the source electrode SE and the drain electrode DE.

The gate electrode GE may be arranged on the gate insulating layer 131. The gate electrode GE may overlap the semiconductor layer ACT, and the gate insulating layer 131 may be interposed between the gate electrode GE and the semiconductor layer ACT.

The gate insulating layer 131 may be arranged on the semiconductor layer ACT. For example, the gate insulating layer 131 may cover the semiconductor layer ACT and the second buffer layer 113, and may insulate the semiconductor layer ACT from the gate electrode GE. The gate insulating layer 131 may include a contact hole through which the first connection electrode CNE1 passes.

The first interlayer insulating layer 133 may cover the gate electrode GE and the gate insulating layer 131. The first interlayer insulating layer 133 may include the contact hole through which the first connection electrode CNE1 passes. The contact hole of the first interlayer insulating layer 133 may be connected to a contact hole of the gate insulating layer 131 and a contact hole of the second interlayer insulating layer 135.

The capacitor electrode CPE may be arranged on the first interlayer insulating layer 133. The capacitor electrode CPE may overlap the gate electrode GE in the thickness direction. The capacitor electrode CPE and the gate electrode GE may form a capacitance.

The second interlayer insulating layer 135 may cover the capacitor electrode CPE and the first interlayer insulating layer 133. The second interlayer insulating layer 135 may define a contact hole through which the first connection electrode CNE1 passes. The contact hole of the second interlayer insulating layer 135 may be connected to the contact hole of the first interlayer insulating layer 133 and the contact hole of the gate insulating layer 131.

The first connection electrode CNE1 may be arranged on the second interlayer insulating layer 135. The first connection electrode CNE1 may electrically connect the drain electrode DE of the thin film transistor TFT to the second connection electrode CNE2. The first connection electrode CNE1 may be in contact with the drain electrode DE of the thin film transistor TFT by being inserted into the contact holes formed in the second interlayer insulating layer 135, the first interlayer insulating layer 133 and the gate insulating layer 131.

The first passivation layer 137 may cover the first connection electrode CNE1 and the second interlayer insulating layer 135. The first passivation layer 137 may protect the thin film transistor TFT. The first passivation layer 137 may include a contact hole through which the second connection electrode CNE2 passes.

The second connection electrode CNE2 may be arranged on the first passivation layer 137. The second connection electrode CNE2 may electrically connect the first connection electrode CNE1 to pixel electrodes AE1 and AE2 of light emitting elements ED1 and ED2. The second connection electrode CNE2 may be in contact with the first connection electrode CNE1 by being inserted into the contact hole formed in the first passivation layer 137.

The second passivation layer 139 may cover the second connection electrode CNE2 and the first passivation layer 137. The second passivation layer 139 may include a contact hole through which the pixel electrodes AE1 and AE2 of the light emitting elements ED1 and ED2 pass.

The light emitting element layer EML1 may be arranged on the first thin film transistor layer TFTL1. The light emitting element layer EML1 includes a pixel defining layer 150 defining a light emission area and a light emitting layer of each of the first to third subpixels SP1, SP2, and SP3, and a plurality of light emitting elements ED1 arranged in the light emission area of each of the first to third subpixels SP1, SP2, and SP3. Each light emitting element ED1 may include a pixel electrode AE1, a light emitting structure EL1, and a common electrode CE.

The plurality of light emitting elements ED1 is arranged in the light emission area of each of the first to third subpixels SP1, SP2, and SP3. Each light emitting element ED1 may emit light of different colors, such as blue and white, depending on the material of the light emitting structure EL1. For example, the first light emitting element arranged in the light emission area of the first subpixel SP1 may emit red light, and the second light emitting element arranged in the light emission area of the second subpixel SP2 may emit green light. The third light emitting element arranged in the light emission area of the third subpixel SP3 may emit blue light.

Each pixel electrode AE1 is formed on the second passivation layer 139. Each pixel electrode AE1 may be respectively arranged in an area corresponding to the light emission area of each subpixel. Each pixel electrode AE1 may be electrically connected to the drain electrode DE of the thin film transistor TFT through the first connection electrode CNE1 and the second connection electrode CNE2. The pixel electrode AE1 for each subpixel may be arranged to be spaced apart from another one on the second passivation layer 139.

Each pixel electrode AE may include a material, which is transparent and has a high work function, such as indium-tin-oxide (ITO), indium-zinc-oxide (IZO), zinc oxide (ZnO), indium oxide (In₂O₃), and the like. When each pixel electrode AE1 is a reflective electrode, the pixel electrode AE1 may have a stacked layer structure in which a material layer having the above-described high work function and a reflective material layer such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or their mixture are stacked. For example, the pixel electrode AE may have a multi-layered structure of ITO/Mg, ITO/MgF, ITO/Ag and ITO/Ag/ITO, but is not limited thereto.

The second display panel 100 may include a pixel defining layer 150 such as a bank arranged on the second passivation layer 139 and the pixel electrode AE1. The pixel defining layer 150 defines each pixel area SP_D and each light transmissive hole forming area OHD. The pixel defining layer 150 is formed on the front surface of the second passivation layer 139, and is formed so that the front surface of each pixel electrode AE1 is exposed by each opening.

The pixel defining layer 150 may be formed as a double layer including an inorganic or organic insulating material layer and an inorganic insulating material layer containing a fluorine-based material. For example, the pixel defining layer 150 may be formed as a double layer including an inorganic insulating material layer containing silicon and an inorganic insulating material layer containing a fluorine-based material. For example, the inorganic insulating material layer may include an inorganic insulating material such as silicon oxide (SiO₂), silicon nitride (Si₃N₄), silicon oxynitride (Si₂N₂O), and the like. The inorganic insulating material layer containing the fluorine-based material may include an inorganic insulating material such as fluorine-based silicon oxide (F—SiO₂), fluorine-based silicon nitride (F—Si₃N₄), fluorine-based silicon oxynitride (F—Si₂N₂O), and the like.

A reflective electrode DEA for each subpixel SP1, SP2 or SP3 may be formed and arranged so that a portion of the reflective electrode DEA overlaps the pixel electrode AE formed in the light emission area for each of the subpixels SP1, SP2, and SP3 or surrounds at least one outer side of the light emitting layer EL1 (e.g., the light emitting structure EL1) while partially overlapping the light emission area, thereby reflecting light from the light emission area in a front direction (e.g., a direction perpendicular to the front surface of the display area) and a side direction.

The reflective electrode DEA for each subpixel SP1, SP2 or SP3 may be formed of the same metal material as that of each pixel electrode AE through a patterning process. That is, each reflective electrode DEA may include indium-tin-oxide (ITO), indium-zinc-oxide (IZO), zinc oxide (zinc oxide: ZnO), indium oxide (In₂O₃) and the like, and may include a transparent material having a high work function. In addition, each reflective electrode DEA may have a stacked structure in which reflective material layers such as silver (Ag), magnesium (Mg), aluminum (Al), platinum (Pt), lead (Pd), gold (Au), nickel (Ni), neodymium (Nd), iridium (Cr), lithium (Li), calcium (Ca), or their mixture are stacked. For example, each reflective electrode DEA may have a multi-layered structure of ITO/Mg, ITO/MgF, ITO/Ag, or ITO/Ag/ITO, but is not limited thereto.

Each reflective electrode DEA may be formed and arranged so that a portion of the reflective electrode DEA overlaps the light emitting layer of the light emitting elements for each of the subpixels SP1, SP2, and SP3 arranged at the outermost or adjacent to the outermost or surrounds at least one outer side of the light emitting layer while partially overlapping the light emitting layer of the light emitting elements, thereby reflecting light from the light emitting layer in a front direction (e.g., a direction perpendicular to the front surface of the display area).

Each light emitting structure EL1 may be arranged on each pixel electrode AE1 including each reflective electrode DEA. In each light emitting structure EL1, the thin film transistor TFT applies a voltage to the pixel electrode AE1 of each light emitting element ED1, and the common electrode CE of the light emitting element ED1 receives a common voltage or a cathode voltage, so that light may be emitted from the light emitting structure EL1 of the light emitting element ED1.

The common electrode CE may be arranged on each light emitting structure EL1. The common electrode CE may be positioned to cover both the light emitting structure EL1 positioned in each pixel area and the pixel defining layer 150.

The common electrode CE includes a transparent conductive material so that light generated in the light emitting structure EL1 may be emitted. The common electrode CE may receive a common voltage or a low potential voltage. When the pixel electrode AE1 receives a voltage corresponding to a data voltage and the common electrode CE receives the low potential voltage, a potential difference is formed between the pixel electrode AE1 and the common electrode CE, whereby light emitted from the light emitting structure EL1. The common electrode CE may include a material layer having a low work function, such as Li, Ca, LiF/Ca, LiF/Al, Al, Mg, Ag, Pt, Pd, Ni, Au Nd, Ir, Cr, BaF, Ba, or their mixture (e.g., a mixture of Ag and Mg). The common electrode CE may further include a transparent metal oxide layer arranged on the material layer having a low work function.

In some examples, only an organic or inorganic layer of a transparent material is formed in the light transmissive hole forming area OHD, and the light transmissive hole OH may be formed as an opening for increasing light transmittance in the light transmissive hole forming area OHD.

The common electrode CE may include a capping layer on a transparent conductive metal layer. The capping layer may serve to protect the transparent conductive metal. That is, the common electrode CE may be a single layer including a conductive metal or may be a multi-layer structure including a conductive metal and a capping layer. A space by a specific gap may be defined on the common electrode CE by overlapping the light emission area for each pixel area.

The touch sensing unit TSU is formed on the front surfaces of the first to third display areas DA1, DA2, and DA3, the first and second folding areas FOU1 and FOU2, and the non-display area NDA.

The touch sensing unit TSU includes a first touch insulating layer TIN1, a connection electrode BE, a second touch insulating layer TIN2, a pressure sensing element QTC, a driving electrode TE, a sensing electrode RE, and a third touch insulating layer TINS3.

The first touch insulating layer TIN1 is formed on the front surface of the touch sensing area TSA and the touch peripheral area TPA, which overlap the main area MA.

The first touch insulating layer TIN1 may include at least one inorganic material of silicon oxide, titanium oxide, aluminum oxide, or silicon nitride (SiNx).

The connection electrode BE and first electrodes TC1 of the pressure sensing element QTC may be formed and arranged on the first touch insulating layer TIN1 of the touch sensing area TSA. The first electrodes TC1 may include the same or substantially the same metal material as that of the connection electrode BE. The connection electrode BE and the first electrodes TC1 may be formed as a single layer or multi-layers made of any one of molybdenum (Mo), aluminum (Al), chromium (Cr), gold (Au), titanium (Ti), nickel (Ni), neodymium (Nd) and copper (Cu), or their alloy.

When the connection electrode BE and the first electrodes TC1 are formed, each of the touch sensing lines RL may be formed and arranged in the touch peripheral area TPA through the same material and the same patterning process as those of the connection electrode BE and the first electrodes TC1. Also, a reference signal transmission line supplying a pressure sensing reference signal to the first electrodes TC1 may be formed simultaneously with the touch sensing lines RL.

Each of the touch sensing lines RL may be patterned in an arrangement shape having a preset length at a preset interval from the adjacent touch sensing lines RL.

The second touch insulating layer TIN2 is formed on the front surface of the first touch insulating layer TIN1 to cover all of the connection electrodes BE and the first electrodes TC1 and the touch sensing lines RL in the touch sensing area TSA. The second touch insulating layer TIN2 is formed to be thicker than the first touch insulating layer TIN1. The second touch insulating layer TIN2 may include at least one inorganic material of silicon nitride, silicon oxide, titanium oxide, aluminum oxide, or the like, and at least one organic material of acrylic resin, epoxy resin, phenol resin, polyamide resin, polyimide resin, or the like.

The driving electrodes TE, the sensing electrodes RE, the dummy electrodes DE, and second electrodes TC2 of the pressure sensing element QTC may be formed and arranged on the second touch insulating layer TIN2 of the touch sensing area TSA, respectively. The driving electrodes TE, the sensing electrodes RE, the dummy electrodes DE, and the second electrodes TC2 of the pressure sensing element QTC may include molybdenum (Mo), aluminum (Al), chromium (Cr), gold (Au), titanium (Ti), nickel (Ni), neodymium (Nd) and copper (Cu), or their alloy.

When the driving electrodes TE, the sensing electrodes RE, the dummy electrodes DE, and the second electrodes TC2 of the pressure sensing element QTC are formed, the first and second touch driving lines TL1 and TL2 and the pressure sensing signal transmission line may be further formed and arranged in the touch peripheral area TPA through the same material and the same pattern process as those of the driving electrodes TE. Each of the first and second touch driving lines TL1 and TL2 and the pressure sensing signal transmission line may be patterned in an arrangement shape having a preset length at a preset interval. The driving electrodes TE formed through the same patterning process may be formed in a state of being electrically connected to the first and second touch driving lines TL1 and TL2.

The driving electrode TE and the sensing electrode RE may overlap the connection electrode BE in the third direction (e.g., the Z-axis direction). The driving electrode TE may be connected to the connection electrode BE through a touch contact hole penetrating the second touch insulating layer TIN2. The sensing electrodes RE may be electrically connected to each of the touch sensing lines RL through the touch contact hole penetrating the second touch insulating layer TIN2.

The third touch insulating layer TINS3 may be formed on the touch sensing area TSA in which the driving electrodes TE, the sensing electrodes RE, the dummy electrodes DE, and the second electrodes TC2 of the pressure sensing element QTC are formed.

The first electrodes TC1 and the second electrodes TC2 of the pressure sensing element QTC transmit a pressure sensing signal corresponding to the pressure sensing reference signal to the display driving circuit 200 through a pressure sensing signal line in accordance with the material and thickness of the second touch insulating layer TIN2. When a touch pressure is applied to the first electrodes TC1 of the pressure sensing element QTC, the pressure sensing element QTC transmits a pressure sensing signal having a voltage magnitude that is variable in response to a pressurizing force to the display driving circuit 200.

The display driving circuit 200 supplies a vibration driving signal to the vibration generating module 500 in response to the pressure sensing signal, so that vibration is generated in the vibration generating module 500 in accordance with a user touch operation.

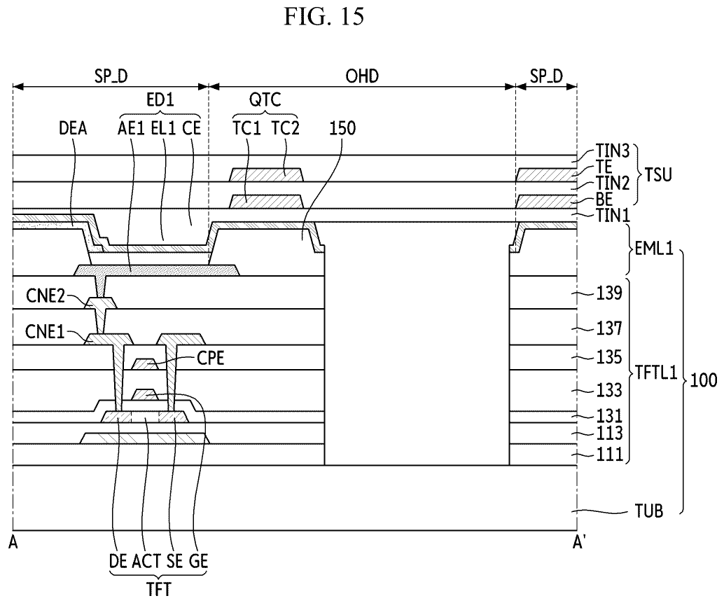

FIG. 15 is a cross-sectional view illustrating a structure of the display device shown in FIG. 6 taken along the line A-A′, according to some other embodiments of the present disclosure.

Referring to FIG. 15, the reflection electrode DEA for each of the subpixels SP1, SP2, and SP3 arranged at the outermost and outer portions of the second and third display areas DA2 and DA3 may be formed and arranged so that a portion of the reflective electrode DEA overlaps the pixel electrode AE formed in the light emission area for each of the subpixels SP1, SP2 and SP or surrounds at least one outer side of the light emitting layer EL1 (e.g., the light emitting structure EL1) while partially overlapping the light emission area, thereby reflecting light from the light emitting layer of each of the subpixels SP1, SP2, and SP3 in a front direction (e.g., a direction perpendicular to the front surface of the display area).

The reflective electrode DEA for each of the subpixels SP1, SP2, and SP3 may be formed through the same metal material and the same patterning process as those of each of the pixel electrodes AE.

Each of the reflective electrodes DEA may be formed and arranged so that a portion of the reflective electrode DEA overlaps the light emitting structures EL1 for each of the subpixels SP1, SP2, and SP3 or surrounds at least one outer side of the light emitting structures EL1 while partially overlapping the light emitting structures EL1, thereby reflecting light from the light emitting layer in a front direction (e.g., a direction perpendicular to the front surface of the display area).

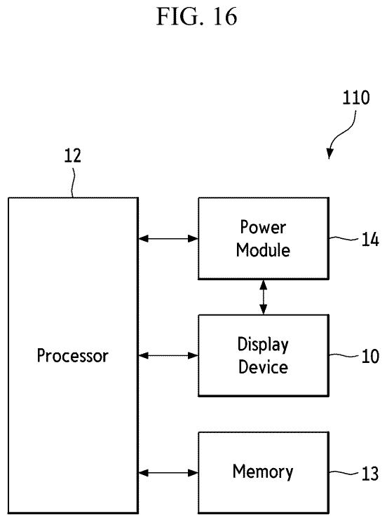

FIG. 16 is a block diagram illustrating an electronic device including a display device according to some embodiments of the present disclosure.

Referring to FIG. 16, an electronic device 110 according to some embodiments may include a display device 10, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information utilized for an operation of the processor 12 or the display device 10 may be stored in the memory 13. When the processor 12 executes an application stored in the memory 13, an image data signal and/or an input control signal is transmitted to the display device 10, and the display device 10 may process the received signal and output image information through a display screen.

The power module 14 may include a power supply module such as a power adapter or a battery device, and a power conversion module converting a power source supplied by the power supply module to generate a power source utilized for the operation of the electronic device 110.

At least one of the respective components of the above-described electronic device 110 may be included in the display device according to the above-described embodiments. Also, some of the individual modules functionally included in one module may be included in the display device 10, and others thereof may be provided separately from the display device 10. For example, the display device 10 includes a display panel, and the processor 12, the memory 13 and the power module 14 may be provided as other devices in the electronic device 110 not the display device 10.

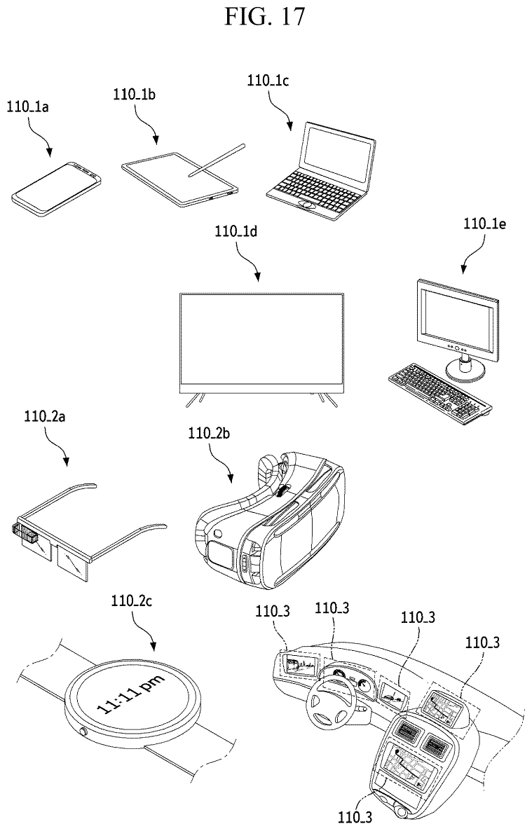

FIG. 17 illustrates schematic diagrams of electronic devices according to some embodiments of the present disclosure.

Referring to FIG. 17, various electronic devices 110 to which the display devices 10 according to some embodiments of the present disclosure are applied may include not only electronic devices for image display, such as a smart phone 110_1a, a tablet PC 110_1b, a laptop 110_1c, a TV 110_1d, and a desk monitor 110_1e, but also wearable electronic devices including display modules such as smart glasses 110_2a, a head mounted display 110_2b, and a smart watch 110_2c, and a vehicle electronic device 110_3 including display modules such as a vehicle dashboard, a center fascia, a center information display (CID) arranged on the dashboard, and a room mirror display. In addition, the display device 10 may be applied as a display member of a television, a laptop computer, a monitor, an advertising board, or Internet of Things (IOT).

In concluding the detailed description, those skilled in the art will appreciate that many variations and modifications can be made to the preferred embodiments without substantially departing from the principles of the present disclosure. Therefore, the disclosed preferred embodiments of the disclosure are used in a generic and descriptive sense only and not for purposes of limitation.

What is claimed is:

1. A display device comprising:
a display panel comprising a first display unit, a second display unit that is folded with the first display unit in an in-folding manner, and a third display unit that is folded with the second display unit in an out-folding manner;
a touch sensing unit arranged on a front surface of the first to third display units and configured to sense a user touch; and
a display driving circuit configured to control an image display operation of pixels arranged in the first to third display units,
wherein each of the second display unit and the third display unit comprises a front surface and a rear surface through which light is transmitted based on a number and a size of light transmissive holes formed in a corresponding display area.

2. The display device of claim 1, wherein the first display unit is configured to display an image through a first display area through which external light is not transmitted and a first folding area extending in one direction of the first display area,
wherein the second display unit extends in one direction of the first folding area, and is configured to display an image through a second display area through which light is transmitted to the front and rear surfaces of the second display unit, and a second folding area extending in one direction of the second display area, and
wherein the third display unit extends in one direction of the second folding area, and is configured to display an image through a third display area through which light is transmitted to the front and rear surfaces of the third display unit.

3. The display device of claim 2, wherein the first folding area is formed in an in-folding structure in which the first display area of the first display unit and the second display area of the second display unit are inwardly arranged to face each other, and
wherein the second folding area is formed in an out-folding structure in which the second display area and the third display area are outwardly arranged so that the rear surfaces of the second display area and the third display area face each other.

4. The display device of claim 3, wherein the first display area comprises a plurality of first unit pixels arranged in a matrix structure, comprising first to third subpixels or first to fourth subpixels, and is configured to display an image through the plurality of first unit pixels arranged in the matrix structure,
wherein the second and third display areas comprise a plurality of second unit pixels arranged in a matrix structure, comprising first to third subpixels and at least one light transmissive hole, and
wherein the plurality of second unit pixels are configured to display an image through the first to third subpixels and to transmit light in front and rear directions through the light transmissive hole.

5. The display device of claim 4, wherein the first display unit comprises an opaque substrate, through which external light is not transmitted, as a base substrate, and
wherein each of the second and third display units comprises a transparent substrate, through which light is transmitted, as a base substrate.

6. The display device of claim 2, wherein the display driving circuit is configured to:
arrange first image data to display a first image according to a light non-transmissive area through the first display area and the first folding area,
arrange second image data to display a second image according to a light transmissive area through the second display area among the second and third display areas that overlap each other and are folded,
align image data in at least one frame unit by arranging third image data to display a third image according to a light transmissive area through the third display area among the second and third display areas that overlap each other and are folded,
modulate a portion of the image data aligned in at least one frame unit, comprising the first to third image data, which corresponds to at least one horizontal line, into analog data voltages, and
sequentially supply the analog data voltages to first to third subpixels of the first display area, the first folding area, the second display area, and the third display area.

7. The display device of claim 2, wherein the display driving circuit arranges first image data to display a first image according to a light non-transmissive area through the first display area and the first folding area,
arranges second image data to display a second image according to a light transmissive area in the second display area among the second and third display areas that overlap each other and are folded,
aligns image data in at least one frame unit by arranging third image data to display a background image of a preset low gray scale or a background image of a black gray scale as a third image in the third display area or a preset partial area of the third display area among the second and third display areas that overlap each other and are folded,
modulates a portion of the image data aligned in at least one frame unit, comprising the first to third image data, which corresponds to at least one horizontal line, into analog data voltages, and
sequentially supplies the analog data voltages to first to third subpixels of the first display area, the first folding area, the second display area, and the third display area.

8. The display device of claim 2, wherein at least one reflective electrode is further formed at an outmost portion of the second and third display areas, at each subpixel being arranged adjacent to the outmost portion in a preset number unit, and at a side adjacent to each subpixel, and
wherein a portion of the reflective electrode overlaps a pixel electrode formed in a light emission area of each subpixel or surrounds at least one outer side of the light emission area while partially overlapping the light emission area, thereby reflecting light emitted from the light emission area in front and side directions.

9. The display device of claim 8, wherein the at least one reflective electrode comprises a metal material that is the same as that of the pixel electrode, and
wherein the at least one reflective electrode is arranged to partially overlap the pixel electrode and a pixel defining layer in a front direction of the pixel electrode, or is formed and arranged to surround at least one outer side and front surface of the light emission area while partially overlapping the light emission area on the front surface of the light emission area.

10. The display device of claim 2, wherein the touch sensing unit further comprises a pressure sensing element comprising first and second electrodes arranged to face each other with a touch insulating layer interposed between the first and second electrodes, and
wherein the display driving circuit is configured to supply a vibration driving signal to a vibration generating module in response to a pressure sensing signal from the pressure sensing element.

11. An electronic device comprising:
a display device configured to display an image;
an image signal processor configured to control an image display timing of the display device; and
a power module configured to provide a power signal to the display device,
wherein the display device comprises:
a display panel comprising a first display unit, a second display unit that is folded with the first display unit in an in-folding manner, and a third display unit that is folded with the second display unit in an out-folding manner;
a touch sensing unit arranged on a front surface of the first to third display units and configured to sense a user touch; and
a display driving circuit configured to control an image display operation of pixels arranged in the first to third display units.

12. The electronic device of claim 11,
wherein each of the second display unit and the third display unit comprise a front surface and a rear surface through which light is transmitted based on a number and a size of light transmissive holes formed in a corresponding display area,
wherein the first display unit is configured to display an image through a first display area through which external light is not transmitted and a first folding area extending in one direction of the first display area,
wherein the second display unit extends in one direction of the first folding area, and is configured to display an image through a second display area through which light is transmitted to the front surface and a rear surface of the second display unit, and a second folding area extending in one direction of the second display area, and
wherein the third display unit extends in one direction of the second folding area, and is configured to display an image through a third display area through which light is transmitted to the front surface and a rear surface of the third display unit.

13. The electronic device of claim 12, wherein the first folding area is formed in an in-folding structure in which the first display area of the first display unit and the second display area of the second display unit are inwardly arranged to face each other, and
wherein the second folding area is formed in an out-folding structure in which the second display area and the third display area are outwardly arranged so that the rear surfaces of the second display area and the third display area face each other.

14. The electronic device of claim 13, wherein the first display area comprises a plurality of first unit pixels arranged in a matrix structure, comprising first to third subpixels or first to fourth subpixels, and is configured to display an image through the plurality of first unit pixels arranged in the matrix structure,
wherein the second and third display areas comprise a plurality of second unit pixels arranged in a matrix structure, comprising first to third subpixels and at least one light transmissive hole, and
wherein the plurality of second unit pixels are configured to display an image through the first to third subpixels and to transmit light in front and rear directions through the light transmissive hole.

15. The electronic device of claim 14, wherein the first display unit comprises an opaque substrate, through which external light is not transmitted, as a base substrate, and
wherein each of the second and third display units comprises a transparent substrate, through which light is transmitted, as a base substrate.

16. The electronic device of claim 12, wherein the display driving circuit is configured to:
arrange first image data to display a first image according to a light non-transmissive area through the first display area and the first folding area,
arrange second image data to display a second image according to a light transmissive area through the second display area among the second and third display areas that overlap each other and are folded,
align image data in at least one frame unit by arranging third image data to display a third image according to a light transmissive area through the third display area among the second and third display areas that overlap each other and are folded,
modulate a portion of the image data aligned in at least one frame unit, comprising the first to third image data, which corresponds to at least one horizontal line, into analog data voltages, and
sequentially supply the analog data voltages to first to third subpixels of the first display area, the first folding area, the second display area, and the third display area.

17. The electronic device of claim 12, wherein the display driving circuit arranges first image data to display a first image according to a light non-transmissive area through the first display area and the first folding area,
arranges second image data to display a second image according to a light transmissive area in the second display area among the second and third display areas that overlap each other and are folded,
aligns image data in at least one frame unit by arranging third image data to display a background image of a preset low gray scale or a background image of a black gray scale as a third image in the third display area or a preset partial area of the third display area among the second and third display areas that overlap each other and are folded,
modulates a portion of the image data aligned in at least one frame unit, comprising the first to third image data, which corresponds to at least one horizontal line, into analog data voltages, and
sequentially supplies the analog data voltages to first to third subpixels of the first display area, the first folding area, the second display area, and the third display area.

18. The electronic device of claim 12, wherein at least one reflective electrode is further formed at an outmost portion of the second and third display areas, at each subpixel being arranged adjacent to the outmost portion in a preset number unit, and at a side adjacent to each subpixel, and
wherein a portion of the reflective electrode overlaps a pixel electrode formed in a light emission area of each subpixel or surrounds at least one outer side of the light emission area while partially overlapping the light emission area, thereby reflecting light emitted from the light emission area in front and side directions.

19. The display device of claim 18, wherein the at least one reflective electrode comprises a metal material that is the same as that of the pixel electrode, and
wherein the at least one reflective electrode is arranged to partially overlap the pixel electrode and a pixel defining layer in a front direction of the pixel electrode, or is formed and arranged to surround at least one outer side and front surface of the light emission area while partially overlapping the light emission area on the front surface of the light emission area.

20. The electronic device of claim 12, wherein the touch sensing unit further comprises a pressure sensing element comprising first and second electrodes arranged to face each other with a touch insulating layer interposed between the first and second electrodes, and
wherein the display driving circuit is configured to supply a vibration driving signal to a vibration generating module in response to a pressure sensing signal from the pressure sensing element.
